(19) United States
(12) Patent Application Publication
(10) Pub. No.: US 2012/0087100 A1
(43) Pub. Date: Apr. 12, 2012

(54) PORTABLE KEYBOARD AND ELECTRONIC DEVICE CARRYING CASE

(76) Inventor: ALLEN KU, Walnut, CA (US)

(21) Appl. No.: 13/038,420

(22) Filed: Mar. 2, 2011

(30) Foreign Application Priority Data
Oct. 12, 2010 (TW) 99219638

(51) Int. Cl. H05K 7/00

(52) U.S. Cl. 361/807

(57) ABSTRACT

A protective carrying apparatus for a portable keyboard unit and a portable electronic device includes a case unit and a portable keyboard unit accommodated therein. The case unit has a first accommodating portion for accommodating the portable electronic device and a second accommodating portion having at least a magnetic coupler. The portable keyboard unit includes a magnetic member that can be selectively coupled to the magnetic coupler of the second accommodating portion of the case unit.

### BACKGROUND OF THE INVENTION

1. Field of the Invention

The present invention is related to a portable keyboard and electronic device carrying case, and more particular to a protective carrying apparatus having magnetic fixing mechanism for securely accommodating a detachable keyboard unit and a portable electronic device.

2. Description of Related Art

Most portable electronic devices, such as tablet computers, personal digital assistants (PDA), and mobile phones, have touch screens. Because a touch screen is a delicate piece of equipment that is easily damaged, specialized case units (such as leather cases) are designed to provide protection for the sophisticated electronic devices and their touch screens.

Although the modem touch screen devices are more intuitive and convenient to operate in comparison to conventional human interface devices (HID) such as keyboards, there remains the need for traditional HIDs particularly when extensive textual inputs are required. Thus, most portable electronic devices are designed to be adaptable with external operating input devices, such as external keyboards, when extensive data inputs are required. However, conventional case units for the portable devices are often designed with compactness in mind and cannot accommodate an additional input device, such as an external keyboard. Thus, the add-on keyboard has to be stored and carried separately from the portable electronic device, causing inconvenience to the device user.

### SUMMARY OF THE INVENTION

The object of the invention is to provide a carrying case of a keyboard and a portable electronic device, including a case unit and a portable keyboard unit accommodated therein. The case unit comprises a first accommodating portion for accommodating a portable electronic device and a second accommodating portion having a magnetic coupler. The keyboard unit is detachably disposed in the second accommodating portion and may be electrically connected to the portable electronic device. The portable keyboard unit includes a magnetic member disposed thereon. The portable keyboard unit can be selectively coupled to the second accommodating portion of the case unit through the attraction force between the magnetic member of the keyboard unit and the magnetic coupler of the case unit.

The other object of the invention is to provide a carrying case for a keyboard and a portable electronic device, including a case unit having a first accommodating portion accommodating a portable electronic device and a second accommodating portion and a detachable keyboard unit disposed in the second accommodating portion and electrically connected to the portable electronic device, wherein at least one magnetic member is disposed on the second accommodating portion, and an magnetic coupler is disposed in the keyboard unit, the magnetic member attracts the magnetic coupler so that the keyboard unit is detachably disposed in the second accommodating portion.

The carrying case of the invention can accommodate keyboard and portable electronic device. It is easy to carry the keyboard along with the portable electronic device.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 is a schematic view of the first embodiment of a carrying case for a keyboard and a portable electronic device of the invention;

FIG. 2 is a schematic view of the second embodiment of a carrying case for a keyboard and a portable electronic device of the invention;

FIG. 3 is a schematic view of the third embodiment of a carrying case for a keyboard and a portable electronic device of the invention;

FIG. 4 is a schematic view of the fourth embodiment of a carrying case for a keyboard and a portable electronic device of the invention;

FIG. 5 is a schematic view of the fifth embodiment of a carrying case for a keyboard and a portable electronic device of the invention.

### DETAILED DESCRIPTION OF THE PREFERRED EMBODIMENTS

### The First Embodiment

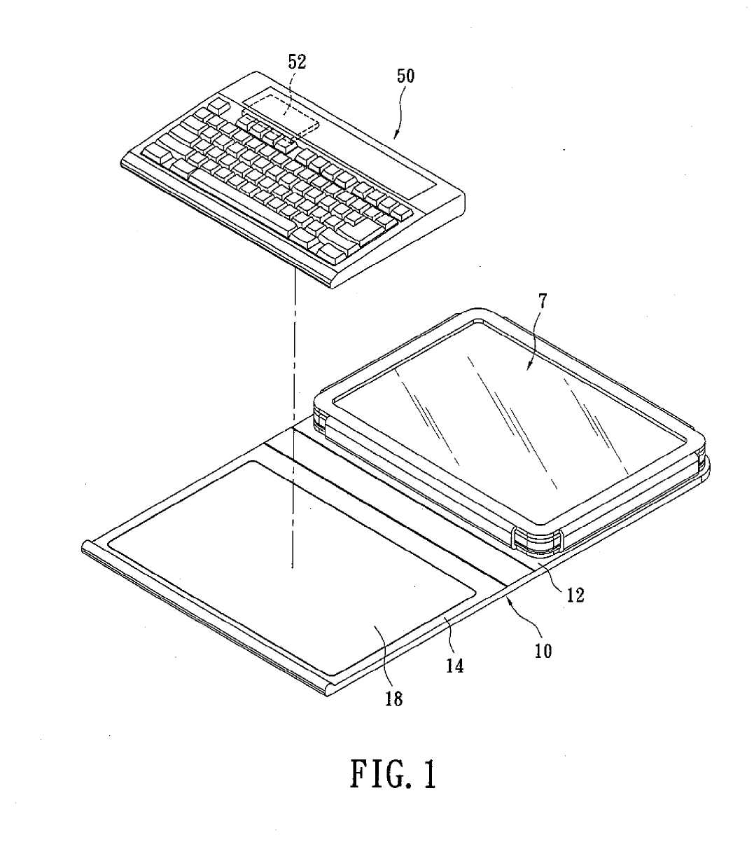

Referring to FIG. 1, a keyboard unit 50 and a portable electronic device 7 are accommodated in a case unit 10. The case unit 10 has a first accommodating portion 12 and a second accommodating portion 14 opposite to the first accommodating portion 12. The portable electronic device 7 is accommodated in the first accommodating portion 12. The keyboard unit 50 is detachably disposed in the second accommodating portion 14. When the portable keyboard unit 50 is used, the keyboard unit 50 can be fixed to the accommodating portion 14. When the keyboard unit 50 is not used, the keyboard unit 50 can be detached from the second accommodating portion 14. The keyboard unit 50 could be electrically connected to the portable electronic device 7 by means of wireless connection, such as Bluetooth, or by wire.

A magnetic member, such as a plate-shaped magnet 52 is disposed in the keyboard unit 50 in this embodiment. A magnetic coupler, such as an iron plate 18 is disposed in the second accommodating portion 14. The keyboard unit 50 is fixed to the second accommodating portion 14 by means of the magnet 52 attracting the iron plate 18. When the keyboard unit 50 is not used, the keyboard unit 50 can be pulled to separate from the second accommodating portion 14.

### The Second Embodiment

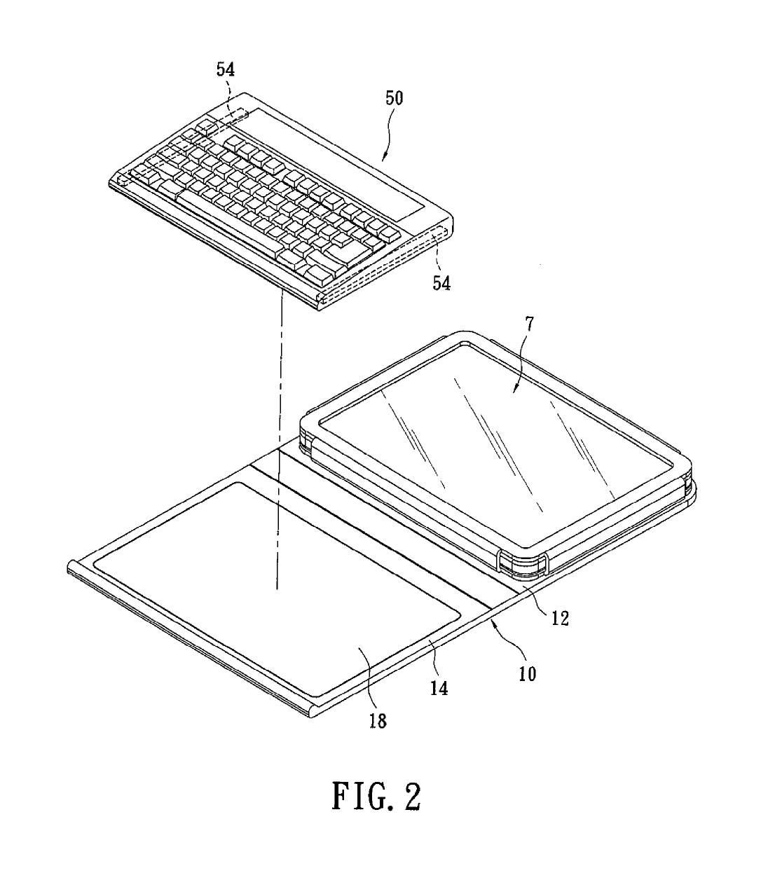

Referring to FIG. 2, similar to the first embodiment, the keyboard unit 50 and the portable electronic device 7 are accommodated in the case unit 10.

Similar to the first embodiment, two stripped magnets 54 are disposed on the bottom of the keyboard unit 50 near the lateral sides of the keyboard unit 50. An iron plate 18 is disposed in the second accommodating portion 14. The keyboard unit 50 is fixed to the second accommodating portion 14 by means of the magnets 54 attracting the iron plate 18. When the keyboard unit 50 is not used, the keyboard unit 50 can be pulled to separate from the second accommodating portion 14.

### The Third Embodiment

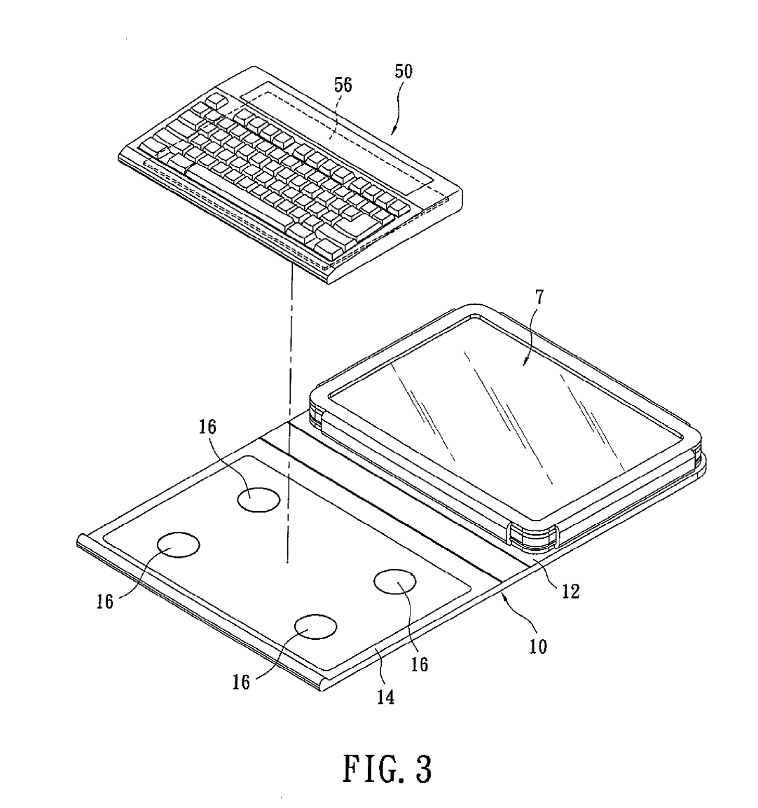

Referring to FIG. 3, similar to the first embodiment, the keyboard unit 50 and the portable electronic device 7 are accommodated in the case unit 10.

The structure of the third embodiment is different from the first and second embodiments. An iron plate 56 having area substantially equal to the bottom of the keyboard unit 50 are disposed on the bottom of the keyboard unit 50. A plurality of circular magnets 16 is disposed in the second accommodating portion 14. There are four circular magnets 16 disposed on four corner of the second accommodating portion 14. The keyboard unit 50 is fixed to the second accommodating portion 14 by means of the magnets 16 attracting the iron plate 56. When the keyboard unit 50 is not used, the keyboard unit 50 can be pulled to separate from the second accommodating portion 14.

In the structure of the third embodiment, since the magnets 16 are disposed on the four corners of the second accommodating portion 14, attractive force is large, the keyboard unit 50 is stably fixed to the second accommodating portion 14. It is not easy to detach the keyboard unit 50.

### The Fourth Embodiment

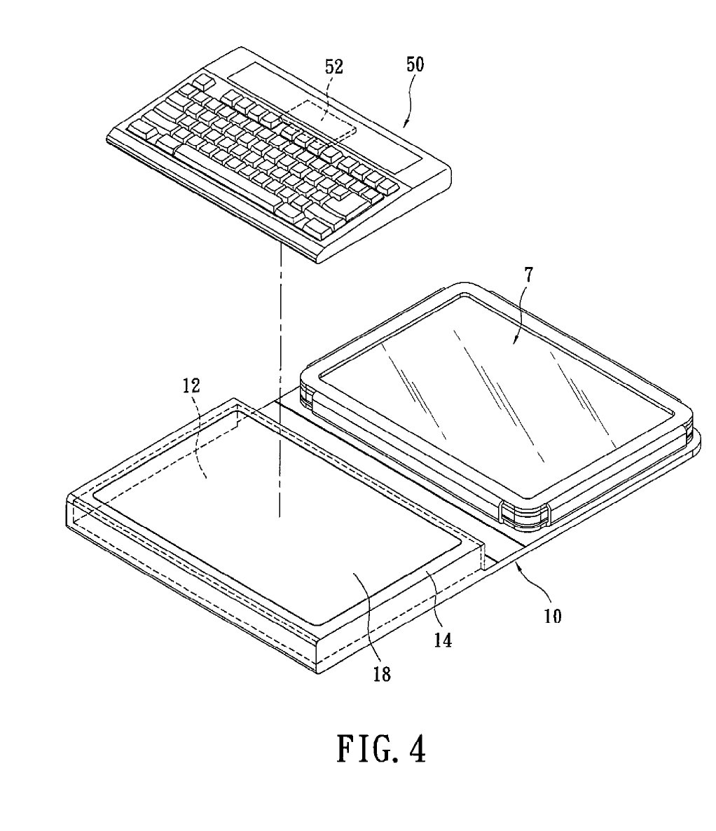

Referring to FIG. 4, similar to the described embodiments, a keyboard unit 50 and a portable electronic device 7 are accommodated in a case unit 10. The case unit 10 has a first accommodating portion 12 and a second accommodating portion 14 opposite to the first accommodating portion 12. In this embodiment, the first accommodating portion 12 includes a bag-shaped structure defining a receiving space. The outer surface of the first accommodating portion 12 forms the second accommodating portion 14. The first accommodating portion 12 and the second accommodating portion 14 are overlapped. The keyboard unit 50 is detachably disposed in the second accommodating portion 14. When the keyboard unit 50 is used, the keyboard unit 50 is fixed in the second accommodating portion 14. When the keyboard unit 50 is not used, the keyboard unit 50 is pulled to separate from the second accommodating portion 14.

A plate-shaped magnet 52 is disposed in the keyboard unit 50. An iron plate 18 is disposed the second accommodating portion 14. The keyboard unit 50 is fixed to the second accommodating portion 14 by means of the magnets 52 attracting the iron plate 18. When the keyboard unit 50 is not used, the keyboard unit 50 can be pulled to separate from the second accommodating portion 14.

When the portable electronic device 7 is not used, it can be accommodated in the first accommodating portion 12. When the portable electronic device 7 is used, it can be pulled out and the keyboard unit 50 is fixed to the second accommodating portion 14.

Although the magnet 54 is disposed in the keyboard unit 50 and the iron plate 18 is disposed in the second accommodating portion 14, it is not limited to the structure. It is possible that the stripped magnets 54 are disposed in the keyboard unit 50 or the magnets 16 are disposed in the second accommodating portion 14, and correspondingly the iron plate 18 is disposed in the second accommodating portion 14 or the iron plate 56 is disposed in the keyboard unit 50.

### The Fifth Embodiment

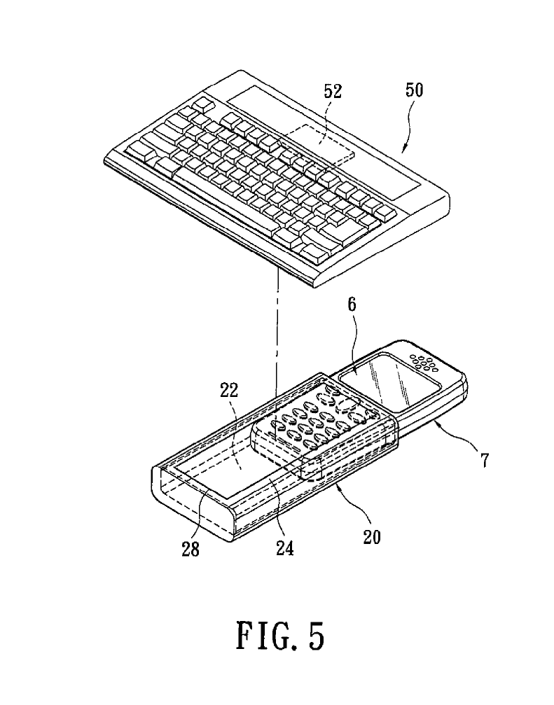

Referring to FIG. 5, a keyboard unit 50 and a portable electronic device 7 are accommodated in a case unit 20. The case unit 20 has a first accommodating portion 22 and a second accommodating portion 24 opposite to the first accommodating portion 22. In this embodiment, the first accommodating portion 22 is a bag-shaped compartment. The outer surface of the first accommodating portion 22 forms the second accommodating portion 24. The first accommodating portion 22 and the second accommodating portion 24 are overlapped. The keyboard unit 50 is detachably disposed in the second accommodating portion 24. When the keyboard unit 50 is used, the keyboard unit 50 is fixed in the second accommodating portion 24. When the keyboard unit 50 is not used, the keyboard unit 50 is pulled to separate from the second accommodating portion 24.

A plate-shaped magnet 52 is disposed in the keyboard unit 50. An iron plate 128 is disposed the second accommodating portion 24. The keyboard unit 50 is fixed to the second accommodating portion 24 by means of the magnets 52 attracting the iron plate 28. When the keyboard unit 50 is not used, the keyboard unit 50 can be pulled to separate from the second accommodating portion 24.

When the portable electronic device 7 is not used, it can be accommodated in the first accommodating portion 22. When the portable electronic device 7 is used, it can be pulled out to reveal the screen 6 and the keyboard unit 50 is fixed to the second accommodating portion 24.

Although the magnet 54 is disposed in the keyboard unit 50 and the iron plate 28 is disposed in the second accommodating portion 24, it is not limited to the structure. It is possible that a magnet is disposed in the second accommodating portion 24 and correspondingly an iron plate is disposed in the second accommodating portion 24.

In the described embodiments, the case unit 10 can be made of animal leather or artificial leather. The keyboard unit 50 can be made of plastic or silicon gel.

The carrying case of the invention can accommodate keyboard and portable electronic device. It is easy to carry the keyboard along with the portable electronic device.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A protective carrying apparatus, comprising:
a case unit having a first accommodating portion for accommodating a portable electronic device and a second accommodating portion having a magnetic coupler; and
a portable keyboard unit having a magnetic member correspondingly and detachably coupled to the magnetic coupler of the second accommodating portion of the case unit and electrically connected to the portable electronic device.

2. The protective carrying apparatus as claimed in claim 1, wherein the magnetic member is disposed in the keyboard unit.

3. The protective carrying apparatus as claimed in claim 2, wherein magnetic member is a plate-shaped magnet.

4. The protective carrying apparatus as claimed in claim 1, wherein the magnetic member is disposed on the bottom of the keyboard unit.

5. The protective carrying apparatus as claimed in claim 4, wherein the magnetic member is a striped magnet disposed on the bottom of the keyboard unit near the lateral sides of the keyboard unit.

6. The protective carrying apparatus as claimed in claim 1, wherein the magnetic coupler is an iron plate disposed in the second accommodating portion.

7. The protective carrying apparatus as claimed in claim 1, wherein the first accommodating portion and the second accommodating portion are opposite.

8. The protective carrying apparatus as claimed in claim 1, wherein the first accommodating portion and the second accommodating portion are overlapped.

9. The protective carrying apparatus as claimed in claim 1, wherein the case unit is made of animal leather.

10. The protective carrying apparatus as claimed in claim 1, wherein the case unit is made of artificial leather.

11. The protective carrying apparatus as claimed in claim 1, wherein the keyboard unit is made of silicone gel.

12. A protective carrying apparatus, comprising:
a case unit having a first accommodating portion for accommodating a portable electronic device and a second accommodating portion having at least one magnetic member disposed thereon; and
a keyboard unit having an magnetic member detachably disposed in the second accommodating portion and electrically connected to the portable electronic device, and an magnetic coupler is disposed in the keyboard unit, the magnetic member attracts the magnetic coupler so that the keyboard unit is detachably disposed in the second accommodating portion.

13. The protective carrying apparatus as claimed in claim 12, wherein the magnetic coupler is disposed on the bottom of the keyboard.

14. The protective carrying apparatus as claimed in claim 13, wherein the magnetic coupler is an iron plate disposed in the second accommodating portion.

15. The protective carrying apparatus as claimed in claim 12, wherein the magnetic member is at least one magnet disposed in the second accommodating portion.

16. The protective carrying apparatus as claimed in claim 12, wherein the first accommodating portion and the second accommodating portion are opposite.

17. The protective carrying apparatus as claimed in claim 12, wherein the first accommodating portion and the second accommodating portion are overlapped.

18. The protective carrying apparatus e as claimed in claim 12, wherein the case unit is made of animal leather.

19. The protective carrying apparatus as claimed in claim 12, wherein the case unit is made of artificial leather.

20. The protective carrying apparatus as claimed in claim 12, wherein the keyboard is made of silicone gel.
